(19) United States
(12) Patent Application Publication
(10) Pub. No.: US 2021/0199692 A1
(43) Pub. Date: Jul. 1, 2021

(54) PROBE PIN HAVING OUTER SPRING

(71) Applicant: OKINS ELECTRONICS CO., LTD, Uiwang-si (KR)

(72) Inventors: Jin Kook JUN, Gunpo-si (KR); Eun Hyeong PYO, Bucheon-si (KR); Won Ho CHOI, Cheonan-si (KR)

(21) Appl. No.: 16/812,147

(22) Filed: Mar. 6, 2020

(30) Foreign Application Priority Data
Dec. 26, 2019 (KR) 10-2019-0174957

(51) Int. Cl. G01R 1/067; G01R 1/04; G01R 1/073

(52) U.S. Cl. CPC G01R 1/06722; G01R 1/07314; G01R 1/0466; G01R 1/06738

(57) ABSTRACT

There is provided a probe pin for performing an electrical inspection between a contact pad of a test apparatus and a conductive ball of a semiconductor device, the probe pin including a cylinder-type bottom plunger connected to the contact pad and configured to slide vertically, a piston-type top plunger connected to the conductive ball and configured to slide vertically, and an outer spring configured to provide an elastic force between the bottom plunger and the top plunger. According to the configuration of the present invention, it is possible to perform a stable inspection process by using the outer spring despite pin miniaturization.

### CROSS-REFERENCE TO RELATED APPLICATION

This application claims priority to and the benefit of Korean Patent Application No. 10-2019-0174957, filed on Dec. 26, 2019, the disclosure of which is incorporated herein by reference in its entirety.

### BACKGROUND

### 1. Field

The present disclosure relates to a probe pin including an outer spring.

### 2. Discussion of Related Art

Generally, probe pins are classified into a double pin type in which both plungers slide and a single pin type in which only one plunger slides.

In the case of the double pin type, there is provided a pipe-shaped housing, upper and lower plungers installed in upper and lower portions of the housing, and a coil spring installed in the housing to provide an elastic force between both of the plungers.

In this arrangement, a test is performed by the upper and lower plungers relatively sliding to approach or recede from each other and also by transmitting or receiving electrical signals by contact upon approach.

### RELATED ART DOCUMENT

### Patent Document

(Patent Document 1) Korean Patent Publication No. 10-2019-0009233

The disclosure of this section is to provide background information relating to the invention. Applicant does not admit that any information contained in this section constitutes prior art.

### SUMMARY

Aspects of the present invention provide a probe pin including an outer spring resistant to a stroke despite repetitive load.

Aspects of the present invention provide a probe pin including an outer spring that has excellent durability and that is easy to stretch and contract like a rod antenna.

Aspects of the invention provide a probe pin that operates in an antenna manner in which a bottom plunger and a top plunger are loaded, that is equipped with an outer spring outside a rod to be resistant to a stroke, and that has a varying ball connection tip to improve a contact characteristic.

According to aspects of the present invention, a probe pin for performing an electrical inspection between a contact pad of a test apparatus and a conductive ball of a semiconductor device includes a cylinder-type bottom plunger connected to the contact pad and configured to slide vertically, a piston-type top plunger connected to the conductive ball and configured to slide vertically, and an outer spring configured to provide an elastic force between the bottom plunger and the top plunger.

### BRIEF DESCRIPTION OF THE DRAWINGS

The above and other aspects, features and advantages of the present invention will become more apparent to those of ordinary skill in the art by describing embodiments thereof in detail with reference to the accompanying drawings, in which:

FIG. 1 is a conceptual view showing a configuration of a probe pin according to a first embodiment of the present invention;

FIGS. 2 to 4 are a perspective view, an exploded perspective view, and a sectional view that show a configuration of the probe pin according to the first embodiment of the present invention, respectively;

FIG. 5 is a sectional view showing a configuration of a probe pin according to a modification of the first embodiment of the present invention;

FIG. 6 includes perspective views illustrating a process of assembling the probe pin according to the first embodiment of the present invention;

FIG. 7 is a conceptual view showing a configuration of a probe pin according to a second embodiment of the present invention;

FIGS. 8 to 10 are a perspective view, an exploded perspective view, and a sectional view showing a configuration of the probe pin according to the second embodiment of the present invention, respectively;

FIG. 11 includes perspective views illustrating a process of assembling the probe pin according to the second embodiment of the present invention;

FIG. 12 includes perspective views illustrating various implementations of a ball connection tip according to an embodiment of the present invention;

FIG. 13 is a diagram showing a concept of a typical Kelvin test;

FIG. 14 is a side view of the probe pin according to the first embodiment of the present invention having a Kelvin-L-shaped ball connection tip implemented as a Kelvin tip;

FIG. 15 is a side view of the probe pin according to the second embodiment of the present invention having a Kelvin-L-shaped ball connection tip implemented as a Kelvin tip;

FIG. 16 includes a perspective view, a left side view, a right side view, a top view, a bottom view, and a front view that show the Kelvin-L-shaped ball connection tip in detail;

FIG. 17 is a side view of the probe pin according to the first embodiment of the present invention having a Kelvin-T-shaped ball connection tip implemented as a Kelvin tip;

FIG. 18 is a side view of the probe pin according to the second embodiment of the present invention having a Kelvin-T-shaped ball connection tip implemented as a Kelvin tip;

FIG. 19 includes a perspective view, a left side view, a right side view, a top view, a bottom view, and a front view that show the Kelvin-T-shaped ball connection tip in detail;

FIG. 20 includes a top view and a side view that show a portion of a test socket having the probe pin having the Kelvin-L-shaped ball connection tip; and

FIG. 21 includes a top view and a side view that show a portion of a test socket having the probe pin having the Kelvin-T-shaped ball connection tip.

### DETAILED DESCRIPTION OF EMBODIMENTS

Advantages and/or features of the present invention and implementation methods thereof will be clarified through the following embodiments described with reference to the accompanying drawings. The present invention may, however, be embodied in different forms and should not be construed as limited to the embodiments set forth herein. Rather, these embodiments are provided so that this disclosure is thorough and complete and fully conveys the scope of the present invention to those skilled in the art. The scope of the present invention is defined by the appended claims. The sizes and relative sizes of layers and regions marked in the drawings may be exaggerated for clarity of description. Like reference numerals refer to like elements throughout.

The embodiments described herein will be described with reference to the top views and the sectional views, which are ideal schematic diagrams of the present invention. Therefore, the diagrams may be modified due to manufacturing techniques and/or tolerances. Therefore, the embodiments of the present invention are not limited to the shown specific forms and may include modifications made according to the manufacturing process. Therefore, the regions illustrated in the drawings have schematic properties, and the shapes of the regions illustrated in the drawings are illustrative of specific shapes of regions of a device and are not intended to limit the scope of the present invention.

In one implementation of a probe pin, a spring is installed inside a housing. In the case of such an inner spring type, since an inner spring is installed in a housing, the inner spring have a smaller diameter than the housing, and thus it is difficult for the inner spring to operate normally, i.e., elastically with respect to a vertically applied load and stroke.

In particular, as a design rule shrinks, the pitch between terminals decreases, and thus the size of the probe pin also tends to decrease. In the case of the inner spring type pogo pin, the durability of the spring gradually weakens, and thus a smooth inspection process cannot be performed.

A probe pin including an outer spring according to embodiments of the present invention having the above-described configuration will be described below in detail with reference to the accompanying drawings.

Probe pins will be described as being used in final test sockets for convenience of description but are not limited thereto and may be used in burn-in test sockets as well.

It is assumed that for an electrical inspection of a semiconductor device such as a wafer with an integrated circuit formed therein, a semiconductor integrated circuit device (e.g., a package integrated circuit (IC), a multi-chip module (MCM), etc.), and the like, a test socket is disposed between a semiconductor device to be inspected and a test apparatus in order to electrically connect a connection terminal (e.g., a contact pad) of the test apparatus and a connection terminal (e.g., a conductive ball) of the semiconductor device.

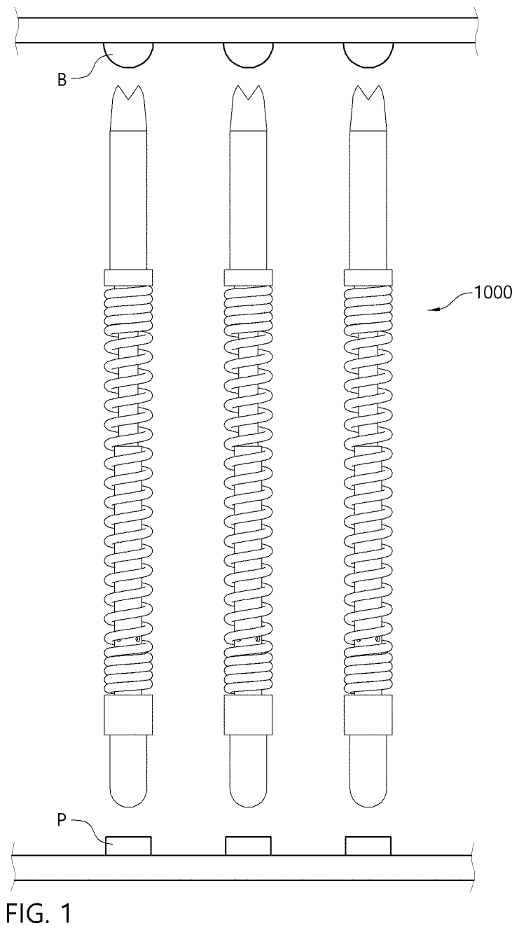

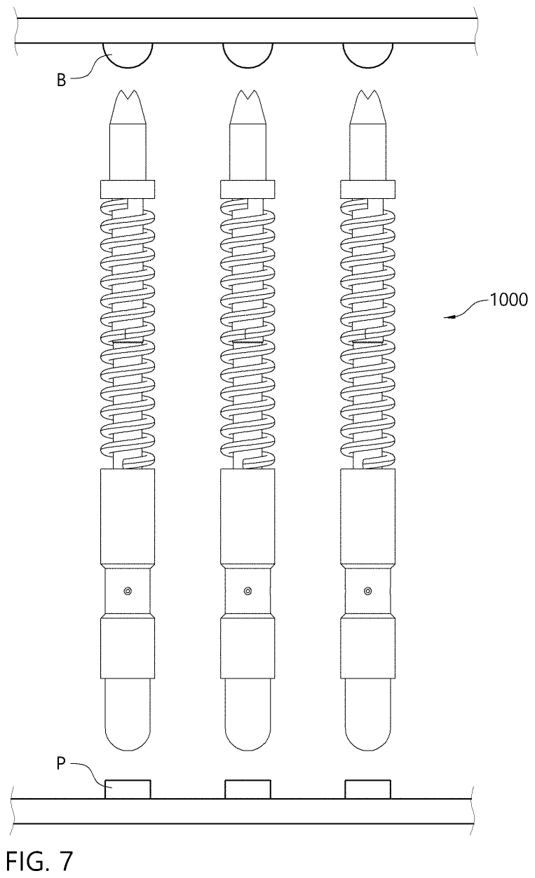

Referring to FIGS. 1 and 7, a probe pin 1000 of the test socket is used to perform an electrical inspection between a semiconductor device and a test apparatus by electrically connecting a contact pad P of the test apparatus and a conductive ball B of an external device, for example, the semiconductor device.

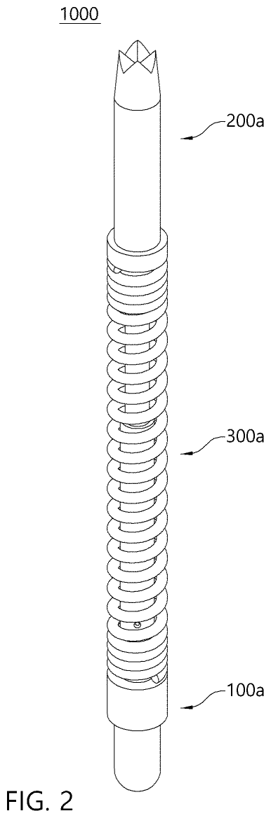

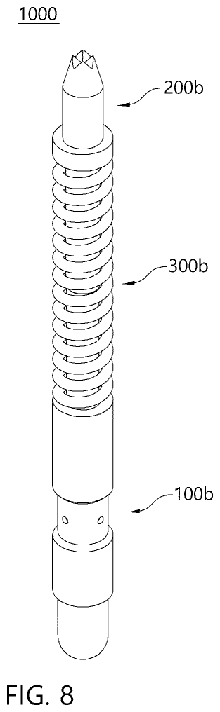

Referring to FIGS. 2 and 8, the probe pin 1000 according to embodiments of the present invention includes a cylinder (or antenna)-type bottom plunger 100a or 100b brought into contact with the contact pad P of the test apparatus (not shown), a piston (or rod)-type top plunger 200a or 200b brought into contact with the conductive ball B of the semiconductor device (not shown), and an outer spring 300a or 300b configured to provide an elastic force between the bottom plunger 100a or 100b and the top plunger 200a or 200b.

### First Embodiment

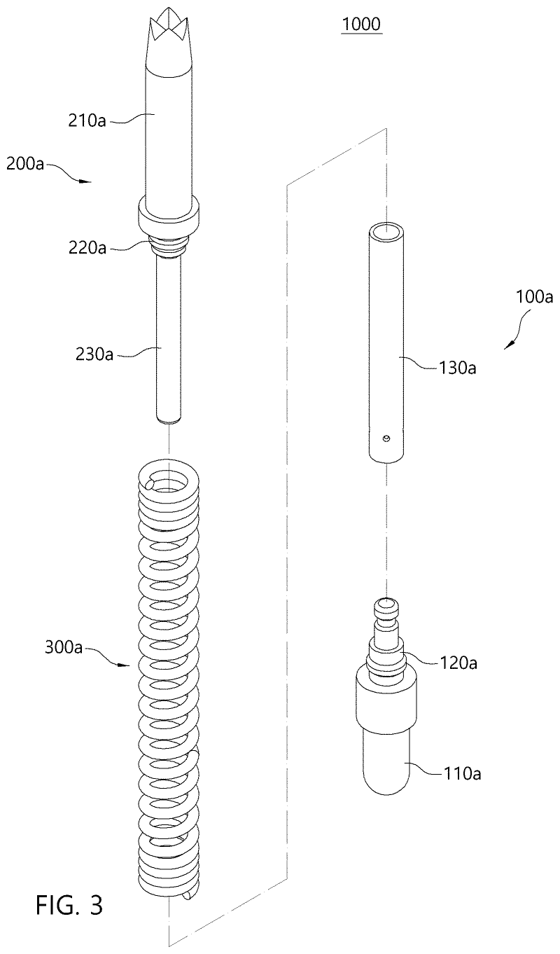

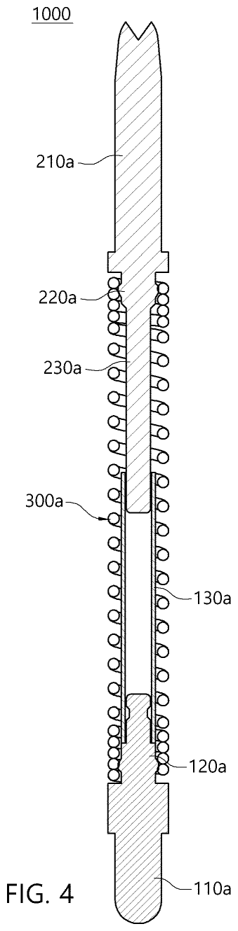

Referring to FIGS. 2 to 4, the bottom plunger 100a includes a pad connection tip 110a brought into direct contact with the contact pad P, a pad fastening pole 120a extending forward (or upward) from the pad connection tip 110a, and a barrel 130a functioning as a cylinder and installed integrally with or separately from the pad fastening pole 120a.

The top plunger 200 includes a ball connection tip 210a brought into direct contact with the conductive ball B, a ball fastening pole 220a extending backward (or downward) from the ball connection tip 210a, and a rod 230a functioning as a piston and extending integrally with the ball fastening pole 220a.

Each of the pad fastening pole 120a and the ball fastening pole 220a have a cylindrical shape with a stepped portion, and the outer spring 300a may be caught and fixed on the stepped portions of the pad fastening pole 120a and the ball fastening pole 220a. At this time, the outer spring 300a includes a finishing portion where both ends have a higher winding density than an elastic portion at the center thereof. Since the finishing portion has a large number of windings, the finishing portion may be caught and firmly fixed on the above-described stepped portion.

The pad fastening pole 120a is shorter than the ball fastening pole 220a, and the barrel 130a is coupled to the pad fastening pole 120a to provide a cylinder. The ball fastening pole 220a is more elongated than the pad fastening pole 120a to provide a piston. Thus, the ball fastening pole 220a may slide in the barrel 130a.

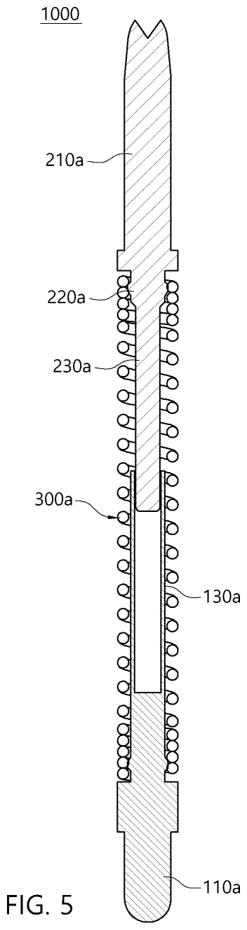

Referring to FIG. 5, the pad fastening pole 120a and the barrel 130a may be integrally connected to each other. In this case, it is not necessary to bond the pad fastening pole 120a to the barrel 130a separately. However, in order to process the pad fastening pole 120a to be formed integrally with the barrel 130a, in embodiments, a drilling method may be applied to the pad fastening pole 120a. However, the pad fastening pole 120a has a very small diameter compared to a length thereof, and thus there is a certain limit to the drill depth. Moreover, even if drilling is possible, precision machining is difficult.

Accordingly, according to another embodiment, the barrel 130a may be provided separately and bonded to the pad fastening pole 120a. At this point, the barrel 130a may be caulked at multiple points (e.g., four points) along an outer diameter thereof to bind the barrel 130a to the pad fastening pole 120a. Here, methods such as spot welding and laser welding as well as mechanical caulking using a jig tool or rolling may be used.

According to this configuration, the configuration according to embodiments the present invention provides high durability against the load of the rod 230a, stroke (or impact), and the like because the rod 230a is stretched and retracted in the barrel 130a in a sliding manner, and in particular, the outer spring 300a is installed outside the rod 230a.

A method of manufacturing the probe pin of the first embodiment will be described below.

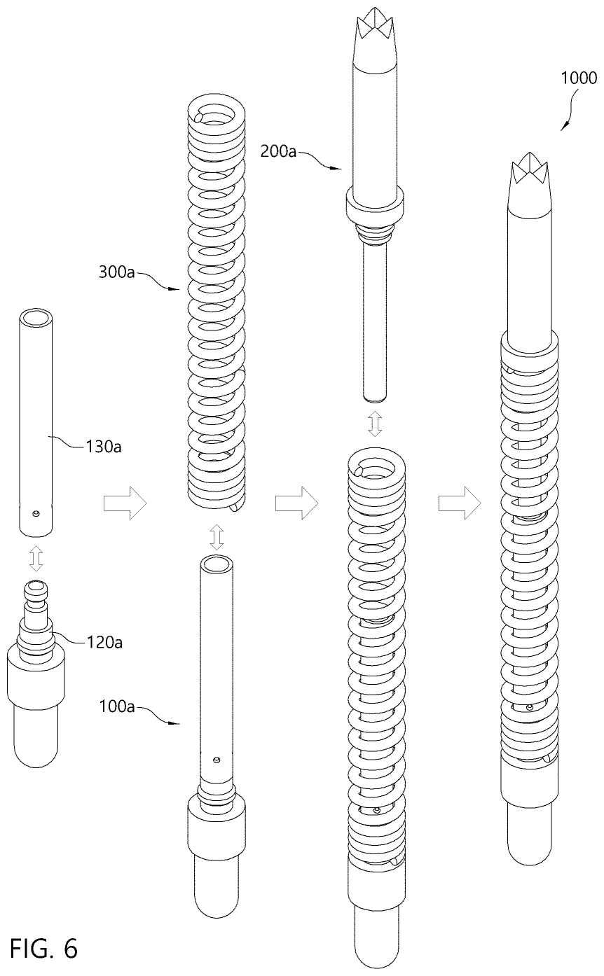

Referring to FIG. 6, the pad connecting tip 110a and the barrel 130a may be connected to each other using the pad fastening pole 120a. The barrel 130a may be fixed to the pad fastening pole 120a using four-point caulking.

One end of the outer spring 300a is inserted through the barrel 130a, and the outer spring 300a is forcibly pressed onto the pad fastening pole 120a. A finishing portion having a higher winding density than an elastic portion may be provided at both ends of the outer spring 300a, and the finishing portion may be caught on and forcibly coupled to the stepped portion of the pad fastening pole 120a.

Likewise, the other end of the outer spring 300a is inserted through the rod 230a, and the outer spring 300a is forcibly pressed onto the ball fastening pole 220a. The above-described finishing portion may be caught on and forcibly coupled to the stepped portion of the ball fastening pole 220a.

The bottom plunger 100 and the top plunger 200 that have been described above may be assembled in the reverse order or simultaneously.

### Second Embodiment

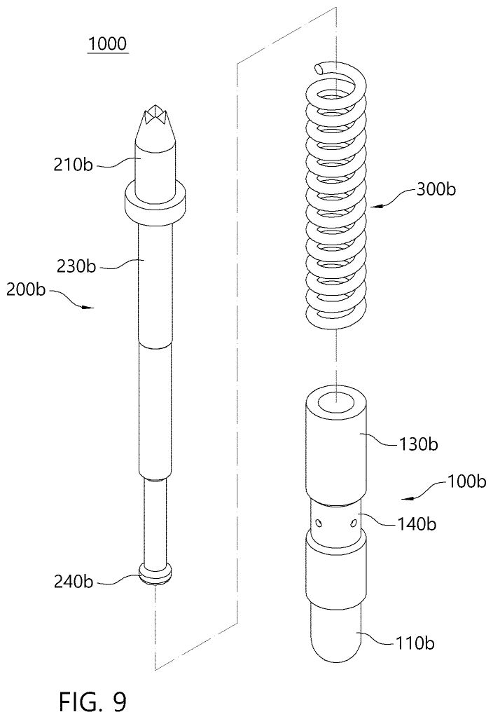

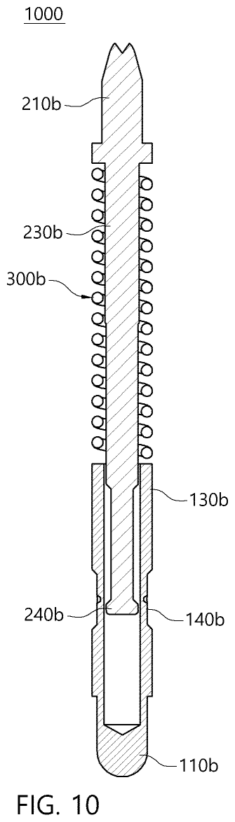

Referring to FIGS. 8 to 10, the bottom plunger 100b includes a pad connection tip 110b brought into direct contact with the contact pad P, a barrel 130b functioning as a cylinder and extending forward (or upward) from the pad connection tip 110b, and a caulking 140b formed on one side of the barrel 130b.

The top plunger 200b includes a ball connection tip 210b brought into direct contact with the conductive ball B, a rod 230b functioning as a piston and extending backward (or downward) from the ball connection tip 210b, and a stopper 240b formed on one end of the rod 230b and bound to the caulking 140b.

An inner diameter of a specific part (hereinafter referred to as a first part, for example, a part protruding outward or a part with the maximum outer diameter) of the bottom plunger 100b and an inner diameter of a specific part (hereinafter referred to as a second part, for example, a part protruding outward or a part with the maximum outer diameter) of the top plunger 200b are smaller than an inner diameter of the outer spring 300b, and an outer diameter of the first part and an outer diameter of the second part are greater than the inner diameter of the outer spring 300b. Thus, the outer spring 300b is caught on the first portion and the second portion to provide a repulsive force between the bottom plunger 100b and the top plunger 200b.

At this time, despite the repulsive force, the stopper 240b is bound to the caulking so that the bottom plunger 100b and the top plunger 200b do not fall out. However, the outer spring 300b does not need to be provided with a separate finishing portion because the outer spring 300b is not fastened to other components by itself.

Meanwhile, the barrel 130b is formed in a relatively short section, and thus is excellent in workability and precision even when the drilling method is applied. Accordingly, the barrel 130b may be formed integrally with the bottom plunger 100b.

A method of manufacturing the probe pin of the second embodiment will be described below.

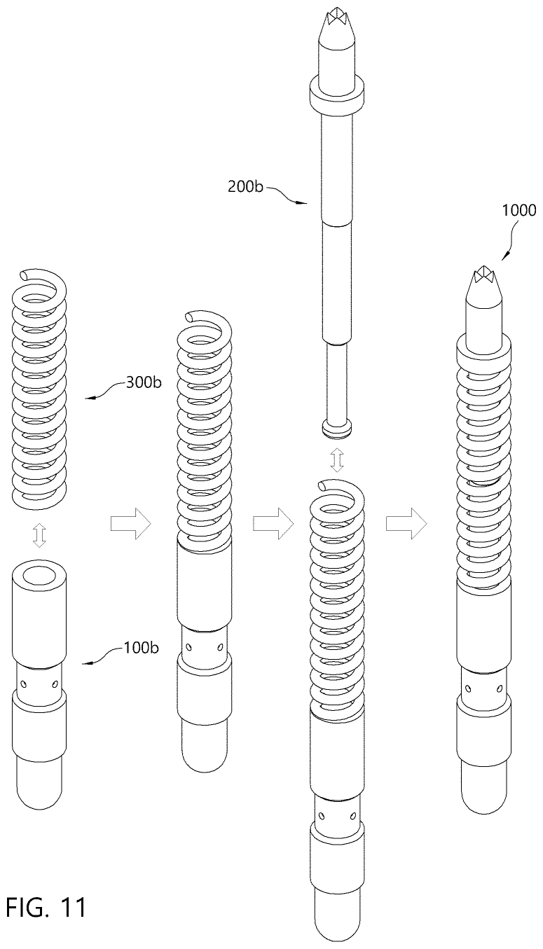

Referring to FIG. 11, the bottom plunger 100b and the top plunger 200b are coupled to each other with the outer spring 300b interposed therebetween. For example, the rod 230b is inserted into the barrel 130b through the inner diameter of the outer spring 300b.

In spite of the outer spring 300b, the pad connection tip 110b and the ball connection tip 210b are sufficiently pressed and coupled to each other, and the stopper 240b passes through the caulking 140b. In this situation, when a caulking process is performed, the stopper 240b is bound to the caulking 140b.

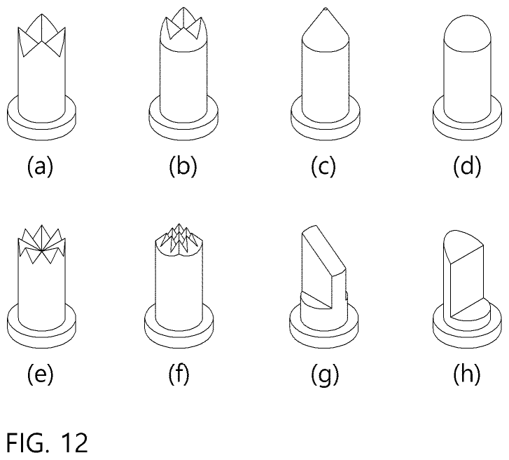

Referring to FIG. 12, the top plungers 200a and 200b are portions brought into contact with the conductive ball B. In particular, a probe that is brought into direct contact with the conductive ball B may be variously designed as the ball connection tips 210a and 210b. In particular, the ball connection tips 210a and 210b may facilitate electrical conduction with the conductive ball by passing through a natural oxide film of the conductive ball.

The ball connection tips 210a and 120b are provided in a three-dimensional shape as a whole. However, a probe region may be provided in a crown shape (see (a)), a reduced crown shape which is a kind of crown shape that has contact portions closer to each other (see (b)), a needle shape with one pointed end (see (c)), a typically spherical or round shape (see (d)), an 8-pointed crown shape having eight probes arranged circumferentially (see (e)), and a 9-pointed crown shape having nine probes aligned horizontally and vertically (see (f)). Also, the probe region may be provided in a central Kelvin-T shape (see (g)) and a laterally eccentric Kelvin-L shape (see (h)). In the case of the Kelvin pin, two probe pins make contact with one contact point.

When multiple contact points are provided in this way, stable contact characteristics may be acquired in spite of alignment tolerance that occurs upon coming in contact with the conductive ball.

Kelvin Pin

Among tests for a semiconductor device, the Kelvin test is for precisely measuring the resistance and the like of the semiconductor device. The measurement is made while two contact terminals are brought into contact with a conductive ball B of the semiconductor device.

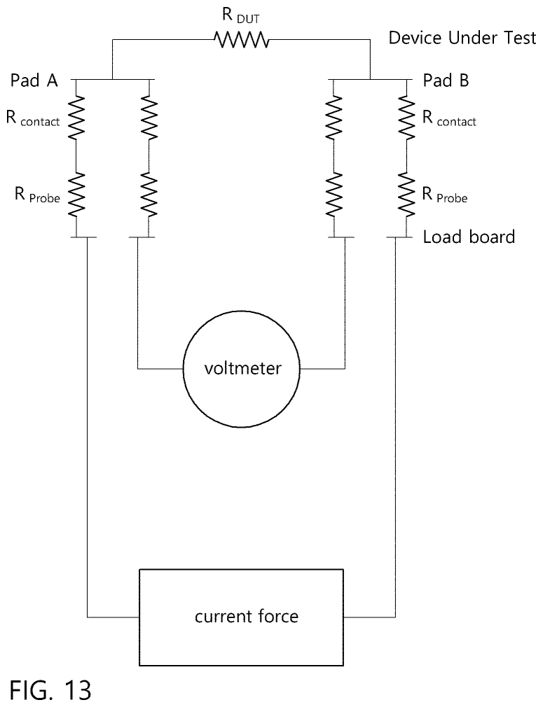

Referring to FIG. 13, generally, the Kelvin test is to measure the resistance and the like of a device to be inspected by measuring current and voltage while two contact terminals are brought into contact with different points in both pads (pad A and pad B) of the device to be inspected. A probe pin for the Kelvin test is referred to as a Kelvin pin.

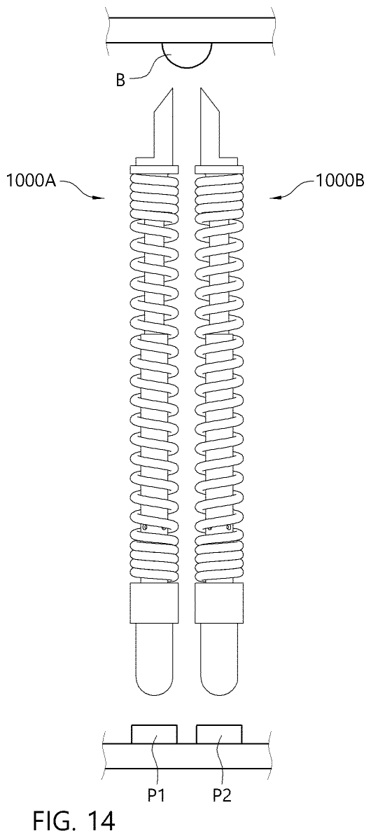

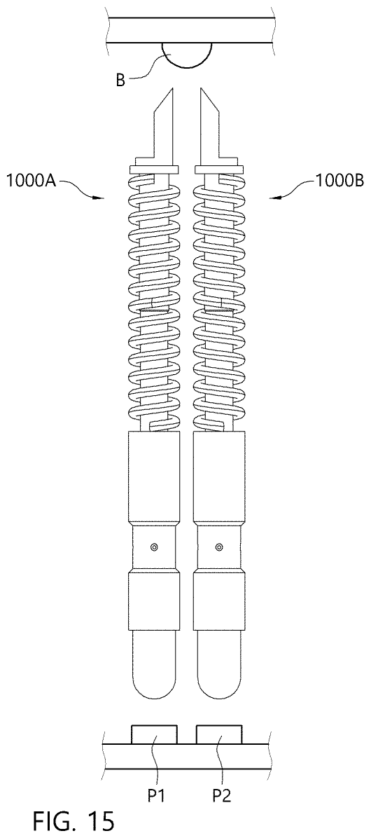

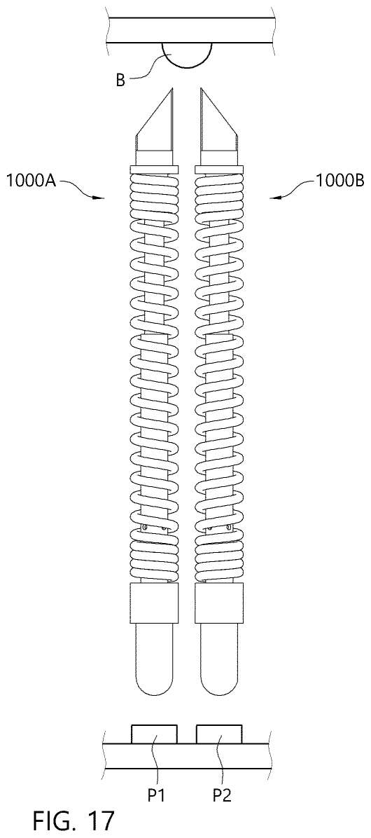

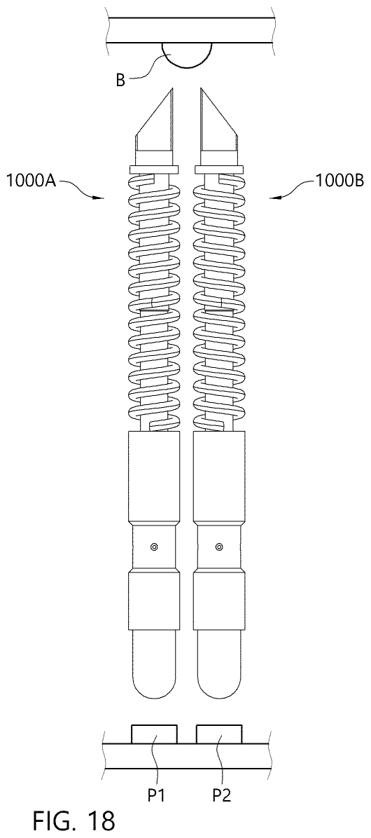

Referring to FIGS. 14, 15, 16, and 17, a pair of Kelvin pins 1000A and 1000B are employed for a conductive ball B of a semiconductor device, and each of the Kelvin pins 1000A and 1000B may be implemented as the probe pin 1000 according to the first embodiment or the second embodiment of the present invention. In this case, a ball connection tip 210 of each of the Kelvin pins 1000A and 1000B may have various shapes as shown in FIG. 12.

However, since the two Kelvin pins 1000A and 1000B are brought into contact with one conductive ball B, it is preferable that the ball connection tips 210 of the Kelvin pins 1000A and 1000B have a Kelvin-L shape or a Kelvin-T shape and have pointed ends placed adjacent to each other and facing toward the center direction of the conductive ball B. That is, each of the Kelvin-L shape and the Kelvin-T shape of the ball connection tips 210 is in a laterally eccentric form in which the pointed ends are biased to one side, that is, in a form in which the one side protrudes not toward the center but toward the ball connection tips 210.

When such a shape and arrangement are made, the separation distance of each of the Kelvin pins 1000A and 1000B may be kept to a minimum to cope with the dense arrangement of conductive balls B or the small area of the conductive ball B, that is, fine pitches. For example, in order to cope with fine pitches, an interval between the pair of ball connection tips 210 may be adjusted so as not to exceed 50 μm.

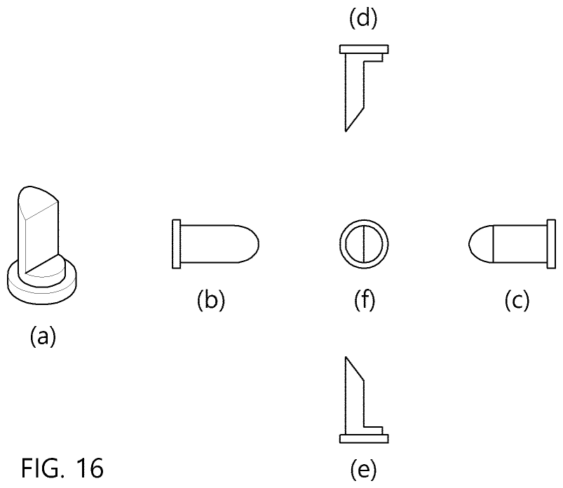

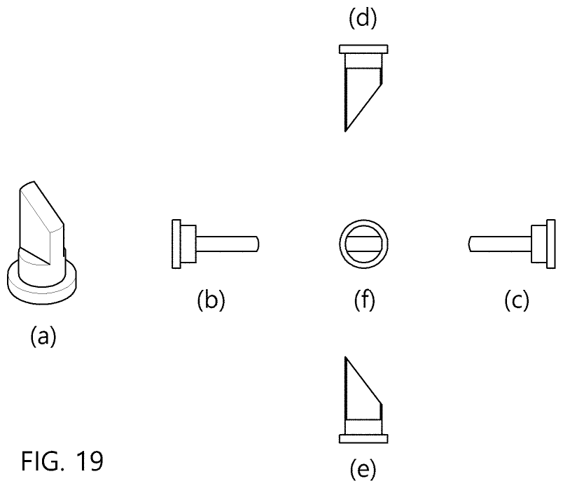

In detail, the Kelvin-L-shaped or Kelvin-T-shaped ball connection tips 210 may be represented using perspective views (see (a)), left side views (see (b)), right side views (see (c)), top views (see (d)), bottom views (see (e)), and front views (see (f)), as shown in FIGS. 16 and 19.

The first Kelvin pin 1000A may be connected to a current supply circuit, and the second Kelvin pin 1000B may be connected to a voltage measurement circuit. In this case, the pair of Kelvin pins 1000A and 1000B have ball connection tips 210 disposed above and connected to the conductive ball B in common and ball connection tips 110 disposed below and connected to two-port contact pads P1 and P2 of the test apparatus, respectively.

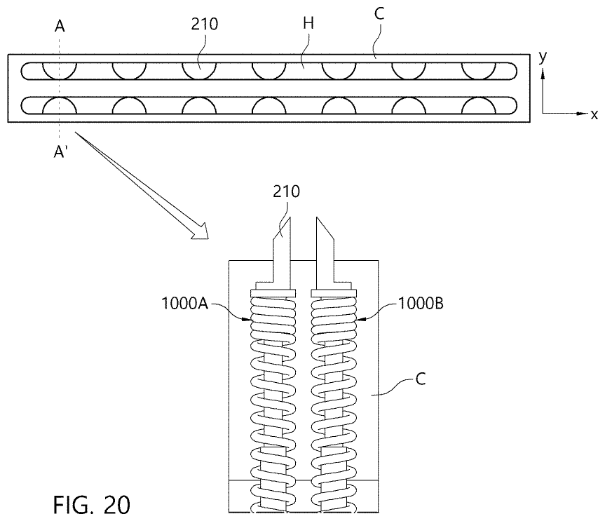

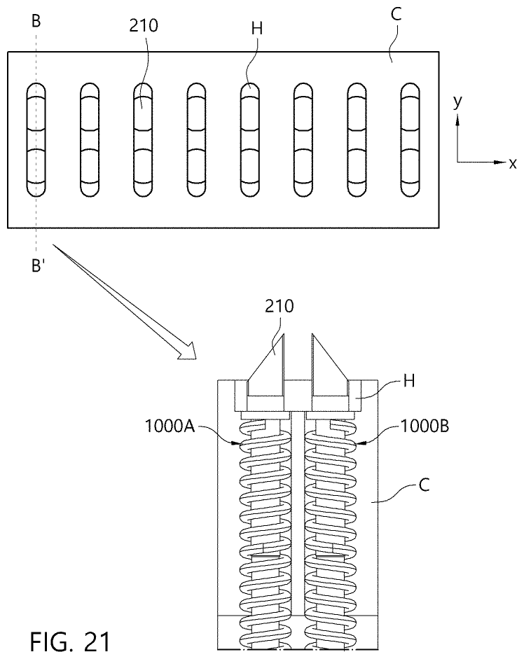

Referring to FIGS. 20 and 21, a Kelvin test socket is to measure current and voltage between the conductive ball B of the semiconductor device and the two-port contact pads P1 and P2 of the test apparatus and includes a first Kelvin pin 1000A connected to a conductive ball B disposed above and a first contact pad P1 disposed below, a second Kelvin pin 1000B connected to the conductive ball B disposed above and a second contact pad P2 disposed below, the second Kelvin pin 1000B being the same as the first Kelvin pin 1000A, and a socket block C installed such that the first and second Kelvin pins 1000A and 1000B are parallel and symmetrical to each other. In this case, the first and second Kelvin pins 1000A and 1000B may have the same configuration and may be installed to face each other in the socket block C.

Socket holes H arranged alongside each other such that the first Kelvin pin 1000A and the second Kelvin pin 1000B are installed symmetrically to each other and have ball connection tips 210 protruding upward may be formed in the socket block C.

Referring to FIG. 20, when the ball connection tips 210 of the first and second Kelvin pins 1000A and 1000B has the Kelvin-L shape, the length direction (x) of the socket holes H and the arrangement direction (y) of the pointed ends of the ball connection tips 210 are perpendicular to each other. Accordingly, the socket holes H may be elongated in the x direction.

Referring to FIG. 21, when the ball connection tips 210 of the first and second Kelvin pins 1000A and 1000B has the Kelvin-T shape, the length direction (x) of the socket holes H and the arrangement direction (y) of the pointed ends of the ball connection tips 210 are parallel to each other. Accordingly, in embodiments, the socket holes H may be elongated in the y direction but may be shorter than those of the Kelvin-L shape. This may be advantageous for coping with fine pitches because of the ease of processing.

Meanwhile, enlarged side views of FIGS. 20 and 21 indicate side views taken along A-A′ and B-B′, respectively. For convenience, FIGS. 20 and 21 are not shown as sectional views.

As described above, according to the configuration of embodiments of the present invention, the following effects can be expected. First, it is possible to provide high durability against vertical loads by installing a spring outside a rod.

Second, it is possible to improve production yield by simplifying the assembly of both plungers and a spring.

Third, it is possible to enhance a consumer's convenience by appropriately responding according to an inspection purpose by variously changing the shape of a ball connection tip.

As described above, it can be seen that the technical spirit of the present invention is the configuration of a probe pin that stably provides an elastic force against load applied to both plungers by having a rod inserted into and stretched and retracted in a pipe-shaped antenna and an outer spring installed outside the rod.

It can also be seen that the technical spirit of the present invention is the configuration of a pair of Kelvin pins capable of coping with fine pitches by having ball connection tips with pointed ends placed facing toward each other and also facing toward the center of a conductive ball.

Within the scope of the basic technical spirit of the present invention, many other modifications will be possible to those skilled in the art.

What is claimed is:

1. A probe pin for performing an electrical inspection between a contact pad of a test apparatus and a conductive ball of a semiconductor device, the probe pin comprising:
a cylinder-type bottom plunger connected to the contact pad and configured to slide vertically;
a piston-type top plunger connected to the conductive ball and configured to slide vertically; and
an outer spring configured to provide an elastic force between the bottom plunger and the top plunger.

2. The probe pin of claim 1, wherein the bottom plunger comprises:
a pad connection tip brought into direct contact with the contact pad;
a pad fastening pole extending forward from the pad connection tip; and
a barrel functioning as a cylinder and installed integrally with or separately from the pad fastening pole.

3. The probe pin of claim 2, wherein the top plunger comprises:
a ball connection tip brought into direct contact with the conductive ball;
a ball fastening pole extending backward from the pad connection tip; and
a rod functioning as a piston and extending integrally with the ball fastening pole.

4. The probe pin of claim 3, wherein the pad fastening pole and the ball fastening pole has a cylindrical shape with a stepped portion, and the outer spring is fixed on the stepped portion.

5. The probe pin of claim 2, wherein the pad fastening pole is formed integrally with the barrel using a drilling method.

6. The probe pin of claim 2, wherein the pad fastening pole is connected to the barrel through caulking.

7. The probe pin of claim 1, wherein the bottom plunger comprises:
a pad connection tip brought into direct contact with the contact pad;
a barrel functioning as a cylinder and extending forward from the pad connection tip; and
a caulking formed on one side of the barrel.

8. The probe pin of claim 7, wherein the top plunger comprises:
a ball connection tip brought into direct contact with the conductive ball;
a rod functioning as a piston and extending backward from the ball connection tip; and
a stopper formed on an end of the rod and bound to the caulking.

9. The probe pin of claim 8, wherein an inner diameter of a first part of the bottom plunger and an inner diameter of a second part of the top plunger are smaller than an inner diameter of the outer spring, and an outer diameter of the first part and an outer diameter of the second part are greater than the inner diameter of the outer spring so that the outer spring is caught on the first part and the second part to provide a repulsive force between the bottom plunger and the top plunger.

10. The probe pin of claim 8, wherein,
the barrel is provided through a drilling method, and
the caulking has a smaller outer diameter than the barrel.

11. The probe pin of claim 1, wherein the probe pin includes a first probe pin connected to a first conductive ball and connected to a first contact pad disposed below and a second probe pin connected to the first conductive ball and connected to a second contact pad disposed below and is used for a Kelvin test.

12. The probe pin of claim 11, wherein the first probe pin and the second probe pin have ball connection tips connected to the conductive ball and formed in a Kelvin-L shape or a Kelvin-T shape that is laterally eccentric, and are installed symmetrically to each other.

13. The probe pin of claim 12, wherein,
socket holes arranged alongside each other are formed such that the first probe pin and the second probe pin are installable symmetrically to each other, and
the first probe pin and the second probe pin have the ball connection tips with ends placed adjacent to each other and facing toward the conductive ball.

14. The probe pin of claim 13, wherein the first probe pin and the second probe pin are installed in a socket block having the socket holes formed such that the ball connection tips protrude upward.

15. The probe pin of claim 14, wherein when the ball connection tips of the first probe pin and the second probe pin have a Kelvin-L shape, the first probe pin and the second probe pin are installed in the socket holes formed in a length direction perpendicular to a direction in which the ends of the ball connection tips are arranged.

16. The probe pin of claim 14, wherein when the ball connection tips of the first probe pin and the second probe pin have a Kelvin-T shape, the first probe pin and the second probe pin are installed in the socket holes formed in a length direction parallel to a direction in which the ends of the ball connection tips are arranged.
